(19) United States
(12) Patent Application Publication
(10) Pub. No.: US 2024/0105497 A1
(43) Pub. Date: Mar. 28, 2024

(54) SUBSTRATE PROCESSING APPARATUS AND HOLDING METHOD OF SUBSTRATE

(71) Applicant: Tokyo Electron Limited, Tokyo (JP)

(72) Inventors: Yosuke Omori, Koshi City (JP); Norifumi Kohama, Koshi City (JP)

(21) Appl. No.: 18/475,593

(22) Filed: Sep. 27, 2023

(30) Foreign Application Priority Data
Sep. 28, 2022 (JP) 2022-155492

(51) Int. Cl. H01L 21/687; H01L 21/67; H01L 21/683; H01L 23/00

(52) U.S. Cl. CPC H01L 21/68764; H01L 21/67259; H01L 21/6838; H01L 24/74; H01L 2224/74; H01L 2924/401

(57) ABSTRACT

A substrate processing apparatus includes a holder configured to hold a substrate by attracting the substrate on an attraction surface. The attraction surface includes an outer attraction portion configured to attract an outer peripheral portion of the substrate and an inner attraction portion configured to attract a portion of the substrate at an inner side than the outer peripheral portion. The holder includes a transforming unit configured to transform the outer attraction portion relative to the inner attraction portion.

### CROSS-REFERENCE TO RELATED APPLICATION

This application claims the benefit of Japanese Patent Application No. 2022-155492 filed on Sep. 28, 2022, the entire disclosure of which is incorporated herein by reference.

### TECHNICAL FIELD

The various aspects and embodiments described herein pertain generally to a substrate processing apparatus and a holding method of a substrate.

### BACKGROUND

Patent Document 1 discloses a substrate processing apparatus (bonding apparatus) equipped with an upper chuck for attracting a substrate at an upper side from above and a lower chuck for attracting a substrate at a lower side from below, and configured to bond the two substrates to face each other. To bond the substrates, the substrate processing apparatus presses a center of the substrate of the upper chuck into contact with a center of the substrate of the lower chuck, bonds the centers of the two substrates to each other by an intermolecular force, and expands this bonding region from the centers to outer peripheries of the substrates.

In this type of substrate processing apparatus, when there is a relative difference in expansion or contraction between bonding surfaces of the two substrates during the bonding, a reference point of the substrate at the upper side and a reference point of the substrate at the lower side are deviated. In particular, the deviation between the reference points tends to increase at outer peripheral portions of the substrates.
Patent Document 1: Japanese Patent Laid-open Publication No. 2015-095579

### SUMMARY

In one exemplary embodiment, a substrate processing apparatus includes a holder configured to hold a substrate by attracting the substrate on an attraction surface. The attraction surface includes an outer attraction portion configured to attract an outer peripheral portion of the substrate and an inner attraction portion configured to attract a portion of the substrate at an inner side than the outer peripheral portion. The holder includes a transforming unit configured to transform the outer attraction portion relative to the inner attraction portion.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a plan view illustrating a bonding apparatus;

FIG. 2 is a side view illustrating the bonding apparatus of FIG. 1;

FIG. 3 is a side view illustrating an example of a first substrate and a second substrate;

FIG. 4 is a flowchart illustrating a bonding method;

FIG. 5 is a plan view illustrating an example of a bonding module according to a first exemplary embodiment;

FIG. 6 is a side view of the bonding module of FIG. 5;

FIG. 7 is a cross sectional view illustrating an example of an upper chuck and a lower chuck;

FIG. 8 is a flowchart illustrating details of a process S109 of FIG. 4;

FIG. 9A is a side view illustrating an example of an operation in a process S112 of FIG. 8;

FIG. 9B is a side view illustrating an operation following that of FIG. 9A;

FIG. 9C is a side view illustrating an operation following that of FIG. 9B;

FIG. 10A is a cross sectional view illustrating an example of an operation in a process S113 of FIG. 8;

FIG. 10B is a cross sectional view illustrating an example of an operation in a process S114 of FIG. 8;

FIG. 10C is a cross sectional view illustrating an operation following that of FIG. 10B;

FIG. 11 is a cross sectional view illustrating a configuration for transforming an outer attraction portion of the lower chuck according to the first exemplary embodiment;

FIG. 12A is a plan view of the lower chuck;

FIG. 12B is a plan view illustrating positions of an attraction surface of the lower chuck when the outer attraction portion of the lower chuck is expanded;

FIG. 13 is an enlarged cross sectional perspective view illustrating a transforming unit of the lower chuck;

FIG. 14A is a cross sectional view illustrating a state in which the outer attraction portion is expanded;

FIG. 14B is a cross sectional view illustrating a state in which the outer attraction portion is contracted;

FIG. 14C is a cross sectional view illustrating a state in which an edge of a substrate is placed at an outer side than a middle position of the outer attraction portion in a width direction;

FIG. 15 is a flowchart illustrating a holding method of the substrate;

FIG. 16 is a plan view of a lower chuck according to a modification example;

FIG. 17 is a cross sectional view illustrating a configuration for transforming an outer attraction portion of a lower chuck according to a second exemplary embodiment;

FIG. 18 is a perspective view illustrating the outer attraction portion divided into a plurality of sections in the lower chuck;

FIG. 19A is a cross sectional view illustrating a first configuration example of the transforming unit;

FIG. 19B is a cross sectional view illustrating a second configuration example of the transforming unit;

FIG. 19C is a cross sectional view illustrating a third configuration example of the transforming unit; and

FIG. 19D is a cross sectional view illustrating a fourth configuration example of the transforming unit.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of the present disclosure will be described with reference to the accompanying drawings. In the various drawings, same parts will be assigned same reference numerals, and redundant description will be omitted. Further, the X-axis direction, the Y-axis direction, and the Z-axis direction used in the following description are axis directions perpendicular to each other. The X-axis direction and the Y-axis direction are horizontal directions, and the Z-axis direction is a vertical direction.

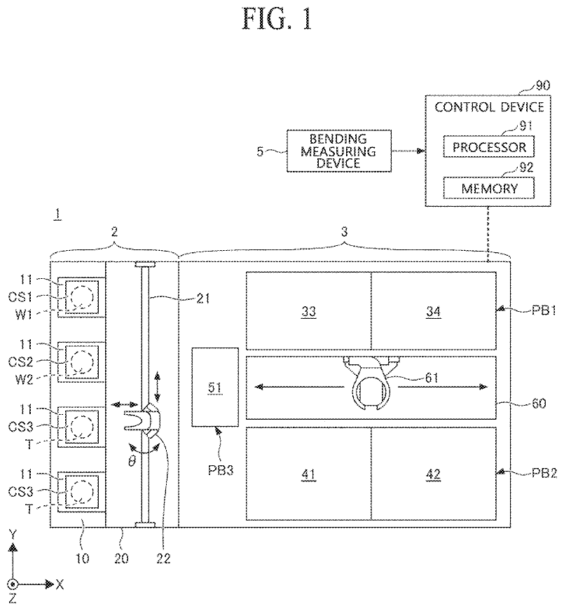

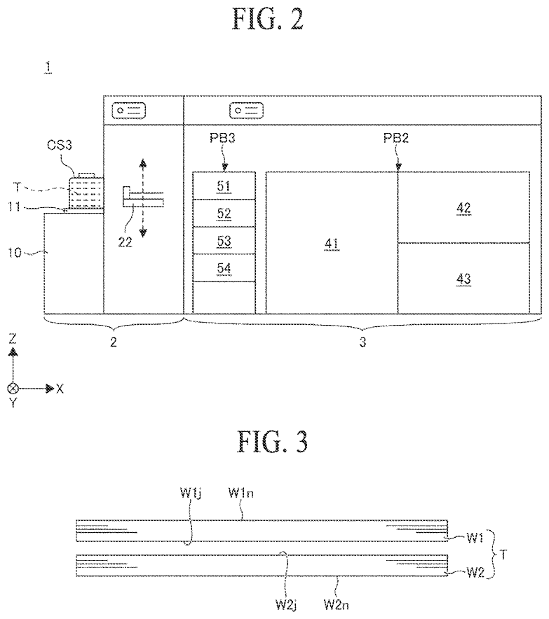

As a substrate processing apparatus according to the present disclosure, a bonding apparatus 1 shown in FIG. 1 and FIG. 2 will be described representatively. The bonding apparatus 1 is configured to produce a combined substrate T by bonding a first substrate W1 and a second substrate W2. At least one of the first substrate W1 and the second substrate W2 is a substrate on which a plurality of electronic circuits are formed on a semiconductor substrate such as, but not limited to, a silicon wafer or a compound semiconductor wafer. One of the first substrate W1 and the second substrate W2 may be a bare wafer on which no electronic circuit is formed. Although not particularly limited, the compound semiconductor wafer may be, for example, a GaAs wafer, a SiC wafer, a GaN wafer, or an InP wafer.

The first substrate W1 and the second substrate W2 are formed on circular plates having substantially the same shape (same diameter). As shown in FIG. 3, the bonding apparatus 1 places the second substrate W2 on the negative Z-axis side of (vertically under) the first substrate W1, and bonds the first substrate W1 and the second substrate W2. Therefore, hereinafter, the first substrate W1 may sometimes be referred to as “upper wafer W1”; the second substrate W2, “lower wafer W2”; and the combined substrate T, “combined wafer T”. In addition, hereinafter, among plate surfaces of the upper wafer W1, the plate surface to be bonded to the lower wafer W2 will be referred to as “bonding surface W1j”, and the plate surface opposite to the bonding surface W1j will be referred to as “non-bonding surface W1n”. Likewise, among plate surfaces of the lower wafer W2, the plate surface to be bonded to the upper wafer W1 will be referred to as “bonding surface W2j”, and the plate surface opposite to the bonding surface W2j will be referred to as “non-bonding surface W2n”.

As depicted in FIG. 1, the bonding apparatus 1 is equipped with a carry-in/out station 2 and a processing station 3 which are arranged in this order along the positive X-axis direction. The carry-in/out station 2 and the processing station 3 are connected as one body.

The carry-in/out station 2 includes a placing table 10 and a transfer section 20. The placing table 10 is equipped with a multiple number of placing plates 11. Provided on the placing plates 11 are cassettes CS1, CS2 and CS3 each of which accommodates therein a plurality of (e.g., 25 sheets of) substrates horizontally. The cassette CS1 accommodates therein upper wafers W1; the cassette CS2, lower wafers W2; and the cassettes CS3, combined wafers T. Further, the upper wafers W1 and the lower wafers W2 are accommodated in the cassettes CS1 and the cassette CS2, respectively, with the bonding surfaces W1j and W2j facing upwards while being aligned in the same direction.

The transfer section 20 is provided adjacent to the positive X-axis side of the placing table 10, and is equipped with a transfer path 21 extending in the Y-axis direction and a transfer device 22 configured to be movable along the transfer path 21. The transfer device 22 is configured to be movable in the X-axis direction as well as in the Y-axis direction and pivotable around the Z-axis, and serves to transfer the upper wafers W1, the lower wafers W2, and the combined wafers T between the cassettes CS1 to CS3 placed on the placing table 10 and a third processing block PB3 of the processing station 3 to be described later.

The processing station 3 has, for example, three processing blocks PB1, PB2, and PB3. The first processing block PB1 is provided on the rear side (positive Y-axis side of FIG. 1) of the processing station 3. The second processing block PB2 is provided on the front side (negative Y-axis side of FIG. 1) of the processing station 3. The third processing block PB3 is provided on the carry-in/out station 2 side (negative X-axis side of FIG. 1) of the processing station 3.

Further, the processing station 3 is equipped with a transfer section 60 having a transfer device 61 in a region surrounded by the first processing block PB1 to the third processing block PB3. For example, the transfer device 61 has a transfer arm configured to be movable in a vertical direction and a horizontal direction and pivotable around a vertical axis. The transfer device 61 is moved within the transfer section 60 to transfer the upper wafers W1, the lower wafers W2, and the combined wafers T to devices within the first processing block PB1, the second processing block PB2, and the third processing block PB3 which are adjacent to the transfer section 60.

The first processing block PB1 includes, for example, a surface modifying apparatus 33 and a surface hydrophilizing apparatus 34. The surface modifying apparatus 33 is configured to modify the bonding surface W1j of the upper wafer W1 and the bonding surface W2j of the lower wafer W2. The surface hydrophilizing apparatus 34 is configured to hydrophilize the modified bonding surfaces W1j and W2j of the upper and lower wafers W1 and W2, respectively.

By way of example, the surfacy modifying apparatus 33 cuts a SiO₂ bond on the bonding surfaces W1j and W2j to form a dangling bond of Si, thus allowing the bonding surfaces W1j and W2j to be hydrophilized afterwards. In the surface modifying apparatus 33, an oxygen gas as a processing gas is excited into plasma and ionized under a decompressed atmosphere, for example. As the oxygen ions are radiated to the bonding surface W1j of the upper wafer W1 and the bonding surface W2j of the lower wafer W2, the bonding surfaces W1j and W2j are plasma-processed and modified. The processing gas is not limited to the oxygen gas, but it may be a nitrogen gas or the like.

The surface hydrophilizing apparatus 34 is configured to hydrophilize the bonding surface W1j of the upper wafer W1 and the bonding surface W2j of the lower wafer W2 with, for example, a hydrophilizing liquid such as pure water. The surface hydrophilizing apparatus 34 also has a function of cleaning the bonding surfaces W1j and W2j. In this surface hydrophilizing apparatus 34, while rotating the upper wafer W1 or the lower wafer W2 held by, for example, a spin chuck, the pure water is supplied onto the upper wafer W1 or the lower wafer W2. Accordingly, the pure water is diffused on the bonding surfaces W1j and W2j, and an OH group is attached to the dangling bond of Si, so that the bonding surfaces W1j and W2j are hydrophilized.

As shown in FIG. 2, the second processing block PB2 includes, for example, a bonding module 41, a first temperature control device 42, and a second temperature control device 43. The bonding module 41 is configured to bond the hydrophilized upper wafer W1 and lower wafer W2 to produce the combined wafer T. The first temperature control device 42 is configured to adjust a temperature distribution of the upper wafer W1 before producing the combined wafer T. The second temperature control device 43 is configured to adjust a temperature distribution of the lower wafer W2 before producing the combined wafer T. In addition, in the present exemplary embodiment, although the first temperature control device 42 and the second temperature control device 43 are provided separately from the bonding module 41, they may be provided as a part of the bonding module 41.

The third processing block PB3 is equipped with a first position adjusting device 51, a second position adjusting device 52, and transition devices 53 and 54 in this order from top to bottom, for example. Further, the places where the individual devices are disposed in the third processing block PB3 are not limited to the example shown in FIG. 2. The first position adjusting device 51 is configured to adjust a direction of the upper wafer W1 in a horizontal direction, and invert the upper wafer W1 upside down so that the bonding surface W1j of the upper wafer W1 faces downwards. The second position adjusting device 52 is configured to adjust a direction of the lower wafer W2 in a horizontal direction. The transition device 53 is configured to temporarily place therein the upper wafer W1. Further, the transition device 54 is configured to temporarily place therein the lower wafer W2 and the combined wafer T.

Referring back to FIG. 1, the bonding apparatus 1 is equipped with a control device (controller) 90 configured to control the individual constituent components. The control device 90 is a control computer having one or more processors 91, a memory 92, a non-illustrated input/output interface, and an electronic circuit. The one or more processors 91 are implemented by one of a CPU, an ASIC, an FPGA, and a circuit composed of a plurality of discrete semiconductors, or a combination thereof, and execute programs stored in the memory 92. The memory 92 forms a storage of the control device 90, including a non-volatile memory and a volatile memory.

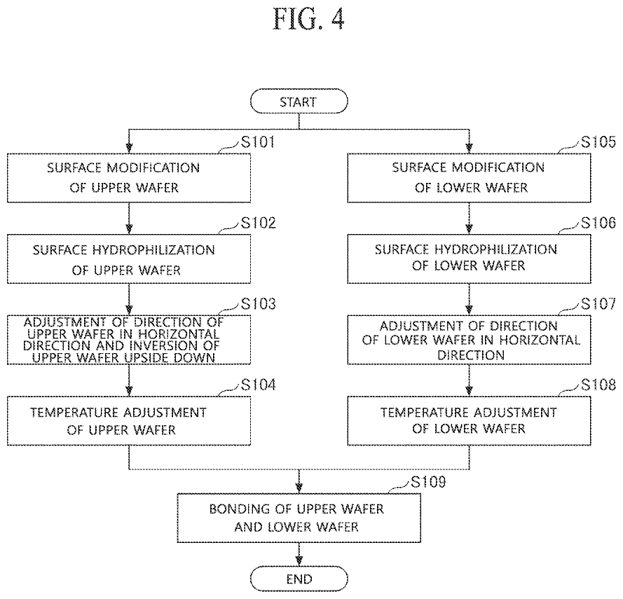

Now, referring to FIG. 4, a bonding method of the present exemplary embodiment will be explained. Processes S101 to S109 shown in FIG. 4 are performed under the control of the control device 90.

In the bonding method, an operator or a transfer robot (not shown) places the cassette CS1 accommodating therein the plurality of upper wafers W1, the cassette CS2 accommodating therein the plurality of lower wafers W2, and the empty cassette CS3 on the placing table 10 of the carry-in/out station 2.

The bonding apparatus 1 takes out the upper wafer W1 in the cassette CS1 by the transfer device 22, and transfers it to the transition device 53 of the third processing block PB3 of the processing station 3. Thereafter, the bonding apparatus 1 takes out the upper wafer W1 from the transition device 53 by the transfer device 61, and transfers it to the surface modifying apparatus 33 of the first processing block PB1.

Next, the bonding apparatus 1 modifies the bonding surface W1j of the upper wafer W1 by the surface modifying apparatus 33 (process S101). The surface modifying apparatus 33 modifies the bonding surface W1j in the state that the bonding surface W1j faces upwards. Then, the transfer device 61 takes out the upper wafer W1 from the surface modifying apparatus 33, and transfers it to the surface hydrophilizing apparatus 34.

Then, the bonding apparatus 1 hydrophilizes the bonding surface W1j of the upper wafer W1 by the surface hydrophilizing apparatus 34 (process S102). The surface hydrophilizing apparatus 34 hydrophilizes the bonding surface W1j in the state that the bonding surface W1j faces upwards. Thereafter, the transfer device 61 takes out the upper wafer W1 from the surface hydrophilizing apparatus 34, and transfers it to the first position adjusting device 51 of the third processing block PB3.

The bonding apparatus 1 adjusts the direction of the upper wafer W1 in the horizontal direction and inverts the upper wafer W1 upside down by the first position adjusting device 51 (process S103). As a result, a notch of the upper wafer W1 is directed in a predetermined direction, and the bonding surface W1j of the upper wafer W1 is turned to face downwards. Thereafter, the transfer device 61 takes out the upper wafer W1 from the first position adjusting device 51, and transfers it to the first temperature control device 42 of the second processing block PB2.

The bonding apparatus 1 adjusts the temperature of the upper wafer W1 by the first temperature control device 42 (process S104). The temperature adjustment of the upper wafer W1 is performed with the bonding surface W1j of the upper wafer W1 facing downwards. Thereafter, the transfer device 61 takes out the upper wafer W1 from the first temperature control device 42, and transfers it to the bonding module 41.

The bonding apparatus 1 performs a processing on the lower wafer W2 in parallel with the above-described processing on the upper wafer W1. First, the bonding apparatus 1 takes out the lower wafer W2 in the cassette CS2 by the transfer device 22, and transfers it to the transition device 54 of the third processing block PB3 of the processing station 3. Then, the transfer device 61 takes out the lower wafer W2 from the transition device 54, and transfers it to the surface modifying apparatus 33 of the first processing block PB1.

The bonding apparatus 1 modifies the bonding surface W2j of the lower wafer W2 by the surface modifying apparatus 33 (process S105). The surface modifying apparatus 33 modifies the bonding surface W2j in the state that the bonding surface W2j faces upwards. Thereafter, the transfer device 61 takes out the lower wafer W2 from the surface modifying apparatus 33, and transfers it to the surface hydrophilizing apparatus 34.

The bonding apparatus 1 hydrophilizes the bonding surface W2j of the lower wafer W2 by the surface hydrophilizing apparatus 34 (process S106). The surface hydrophilizing apparatus 34 hydrophilizes the bonding surface W2j in the state that the bonding surface W2j faces upwards. Then, the transfer device 61 takes out the lower wafer W2 from the surface hydrophilizing apparatus 34, and transfers it to the second position adjusting device 52 of the third processing block PB3.

The bonding apparatus 1 adjusts the direction of the lower wafer W2 in the horizontal direction by the second position adjusting device 52 (process S107). As a result, a notch of the lower wafer W2 is directed toward a predetermined direction. Thereafter, the transfer device 61 takes out the lower wafer W2 from the second position adjusting device 52, and transfers it to the second temperature control device 43 of the second processing block PB2.

The bonding apparatus 1 adjusts the temperature of the lower wafer W2 by the second temperature control device 43 (process S108). The temperature adjustment of the lower wafer W2 is performed with the bonding surface W2j of the lower wafer W2 facing upwards. Thereafter, the transfer device 61 takes out the lower wafer W2 from the second temperature control device 43, and transfers it to the bonding module 41.

Then, the bonding apparatus 1 bonds the upper wafer W1 and the lower wafer W2 in the bonding module 41 to produce the combined wafer T (process S109). After the production of the combined wafer T, the transfer device 61 takes out the combined wafer T from the bonding module 41, and transfers it to the transition device 54 of the third processing block PB3.

Finally, the bonding apparatus 1 takes out the combined wafer T from the transition device 54 by the transfer device 22, and transfers it to the cassette CS3 on the placing table 10. Thus, the series of processes are ended.

### First Exemplary Embodiment

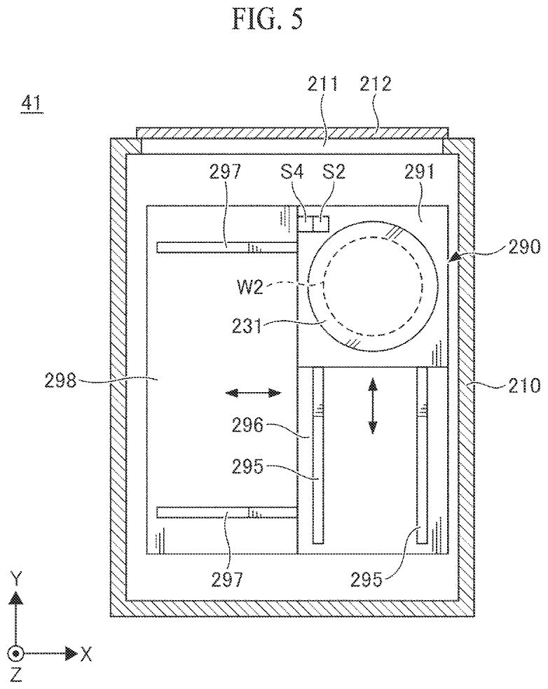

Now, with reference to FIG. 5 to FIG. 7, an example of the bonding module 41 according to a first exemplary embodiment will be described. As depicted in FIG. 5, the bonding module 41 is equipped with a processing vessel 210 having a sealable inside. A carry-in/out opening 211 is formed on a side surface of the processing vessel 210 on the transfer section 60 side, and an opening/closing shutter 212 is provided at the carry-in/out opening 211. The upper wafer W1, the lower wafer W2, and the combined wafer T are carried in and out through the carry-in/out opening 211.

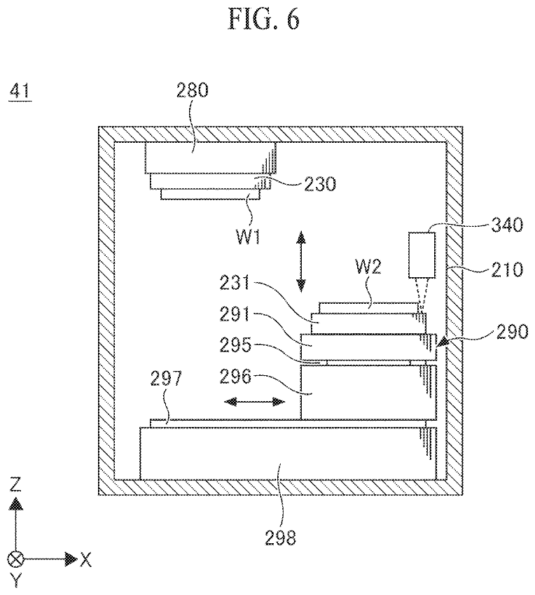

As shown in FIG. 6, an upper chuck 230 and a lower chuck 231 are provided inside the processing vessel 210. The upper chuck 230 holds the upper wafer W1 from above while allowing the bonding surface W1j of the upper wafer W1 to face downwards. Further, the lower chuck 231 is disposed below the upper chuck 230, and holds the lower wafer W2 from below while allowing the bonding surface W2j of the lower wafer W2 to face upwards.

The upper chuck 230 is supported by a supporting member 280 provided on a ceiling surface of the processing vessel 210. Meanwhile, the lower chuck 231 is supported by a first lower chuck mover 291 provided below the lower chuck 231.

The first lower chuck mover 291 moves the lower chuck 231 in a horizontal direction (Y-axis direction) as will be described later. Further, the first lower chuck mover 291 is configured to be capable of moving the lower chuck 231 in a vertical direction and rotating it around a vertical axis.

The first lower chuck mover 291 is mounted to a pair of rails 295 provided on a bottom surface side of the first lower chuck mover 291 and extending in the horizontal direction (Y-axis direction). The first lower chuck mover 291 is configured to be movable along the rails 295. The rails 295 are provided on the second lower chuck mover 296.

The second lower chuck mover 296 is mounted to a pair of rails 297 provided on a bottom surface side of the second lower chuck mover 296 and extending in a horizontal direction (X-axis direction). The second lower chuck mover 296 is configured to be movable along the rails 297. In addition, the pair of rails 297 are disposed on a placing unit 298 which is provided on a bottom surface of the processing vessel 210.

The first lower chuck mover 291 and the second lower chuck mover 296 constitute a moving mechanism 290. The moving mechanism 290 moves the lower chuck 231 relative to the upper chuck 230. Further, the moving mechanism 290 moves the lower chuck 231 between a substrate delivery position and a bonding position.

The substrate delivery position is a position where the upper chuck 230 receives the upper wafer W1 from the transfer device 61, the lower chuck 231 receives the lower wafer W2 from the transfer device 61, and the lower chuck 231 delivers the combined wafer T to the transfer device 61. The substrate delivery position is a position where a carry-out of the combined wafer T produced by the n^{th} (n is a natural number equal to or larger than 1) bonding and a carry-in of the upper wafer W1 and the lower wafer W2 to be bonded by the (n+1)^{th} bonding are performed in succession. The substrate delivery position is, for example, a position shown in FIG. 5 and FIG. 6.

When handing the upper wafer W1 over to the upper chuck 230, the transfer device 61 advances to a space directly below the upper chuck 230. Further, when receiving the combined wafer T from the lower chuck 231 and handing the lower wafer W2 over to the lower chuck 231, the transfer device 61 advances to a space directly above the lower chuck 231. The upper chuck 230 and the lower chuck 231 are placed sideways apart and a distance between the upper chuck 230 and the lower chuck 231 in a vertical direction is large so that the transfer device 61 advances therebetween easily.

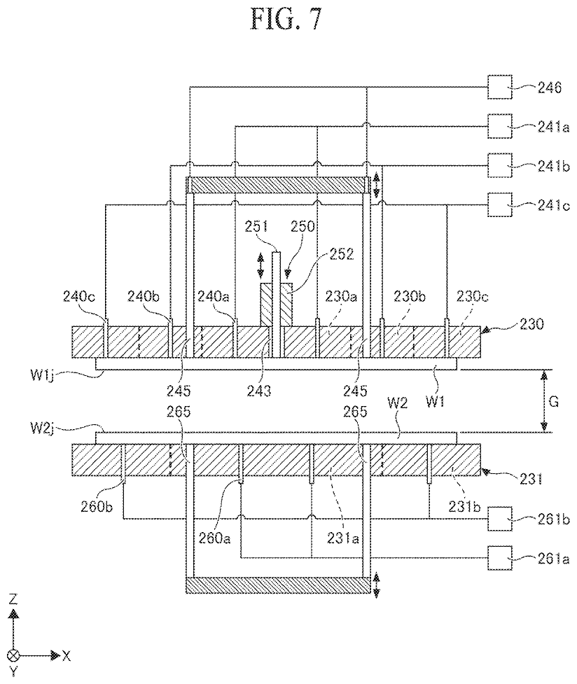

Meanwhile, the bonding position is a position (facing position) where the upper wafer W1 and the lower wafer W2 are made to face each other with a preset distance therebetween. The bonding position is, for example, a position shown in FIG. 7. At the bonding position, the distance between the upper wafer W1 and the lower wafer W2 in the vertical direction is narrower than that at the substrate delivery position. Further, at the bonding position, the upper wafer W1 and the lower wafer W2 overlap each other when viewed from the vertical direction, unlike at the substrate delivery position.

The moving mechanism 290 moves the relative positions of the upper chuck 230 and the lower chuck 231 in horizontal directions (both the X-axis direction and the Y-axis direction) and a vertical direction. Although the moving mechanism 290 moves the lower chuck 231 in the present exemplary embodiment, it may move any one of the lower chuck 231 and the upper chuck 230, or both of them. Further, the moving mechanism 290 may rotate the upper chuck 230 or the lower chuck 231 around a vertical axis.

As illustrated in FIG. 7, the upper chuck 230 is divided into a plurality of (for example, three) regions 230a, 230b, and 230c along a radial direction of the upper chuck 230. These regions 230a, 230b, and 230c are provided in this order from a center of the upper chuck 230 toward an outer periphery thereof. The region 230a is formed in a circular shape when viewed from the top, and the regions 230b and 230c are formed in an annular shape when viewed from the top.

Suction lines 240a, 240b, and 240c are independently provided in the regions 230a, 230b, and 230c, respectively. Different vacuum pumps 241a, 241b, and 241c are connected to the suction lines 240a, 240b, and 240c, respectively. The upper chuck 230 is capable of vacuum-attracting the upper wafer W1 in each of the regions 230a, 230b, and 230c individually.

The upper chuck 230 is provided with a multiple number of holding pins 245 configured to be movable up and down in a vertical direction. The plurality of holding pins 245 are connected to a vacuum pump 246, and the upper wafer W1 is vacuum-attracted to the holding pins 235 by the operation of the vacuum pump 246. The upper wafer W1 is vacuum-attracted to lower ends of the plurality of holding pins 245. Instead of the plurality of holding pins 245, a ring-shaped attraction pad may be used.

The plurality of holding pins 245 are protruded from an attraction surface of the upper chuck 230 as they are lowered by a non-illustrated driving unit. In this state, the plurality of holding pins 245 receives the upper wafer W1 from the transfer device 61 by vacuum-attracting it. Thereafter, the plurality of holding pins 245 are raised, allowing the upper wafer W1 to come into contact with the attraction surface of the upper chuck 230. Then, the upper chuck 230 vacuum-attracts the upper wafer W1 horizontally in the respective regions 230a, 230b, and 230c by the operations of the vacuum pumps 241a, 241b, and 241c, respectively.

In addition, the upper chuck 230 has, at the center thereof, a through hole 243 formed through the upper chuck 230 in a vertical direction. A pushing member 250 is inserted through the through hole 243. The pushing member 250 presses the center of the upper wafer W1 spaced apart from the lower wafer W2, thus bringing the upper wafer W1 into contact with the lower wafer W2.

The pushing member 250 has a pushing pin 251 and an outer cylinder 252 serving as an elevation guide for the pushing pin 251. The pushing pin 251 is inserted through the through hole 243 by, for example, a driving unit (not shown) having a motor therein, and is protruded from the attraction surface of the upper chuck 230, pressing the center of the upper wafer W1.

Moreover, the lower chuck 231 is also partitioned into a plurality of (for example, two) regions 231a and 231b along the radial direction of the lower chuck 231. These regions 231a and 231b are provided in this order from the center of the lower chuck 231 toward the outer periphery thereof. The region 231a is formed in a circular shape when viewed from the top, and the region 231b is formed in an annular shape when viewed from the top. The region 231b may have a plurality of arc-shaped zones (small regions) along the circumferential direction thereof.

Suction lines 260a and 260b are independently provided in the regions 231a and 231b, respectively. Separate vacuum pumps 261a and 261b are connected to the suction lines 260a and 260b, respectively. With this configuration, the lower chuck 231 is capable of vacuum-attracting the lower wafer W2 in each of the regions 231a and 231b independently.

The lower chuck 231 is provided with a plurality of (for example, three) holding pins 265 configured to be movable up and down in a vertical direction. The lower wafer W2 is placed on upper ends of the plurality of holding pins 265. Further, the lower wafer W2 may be vacuum-attracted to the upper ends of the plurality of holding pins 265.

The plurality of holding pins 265 are protruded from the attraction surface of the lower chuck 231 as they are raised. In this state, the plurality of holding pins 265 receive the lower wafer W2 from the transfer device 61. After that, the plurality of holding pins 265 are lowered, thus allowing the lower wafer W2 to come into contact with the attraction surface 300 of the lower chuck 231. Then, the lower chuck 231 vacuum-attracts the lower wafer W2 horizontally in the plurality of regions of the attraction surface 300.

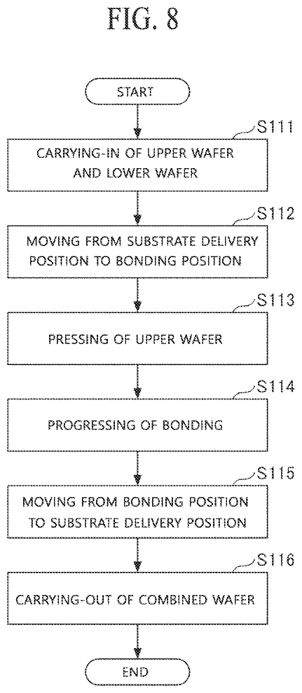

Now, with reference to FIG. 8 to FIG. 10C, the process of manufacturing the combined wafer T in the process S109 of FIG. 4 will be described in detail. As depicted in FIG. 8, the control device 90 controls the transfer device 61 to carry the upper wafer W1 and the lower wafer W2 into the bonding module 41 (process S111). The relative positions of the upper chuck 230 and the lower chuck 231 after being carried in are as shown in FIG. 5 and FIG. 6, that is, they are at the substrate delivery position.

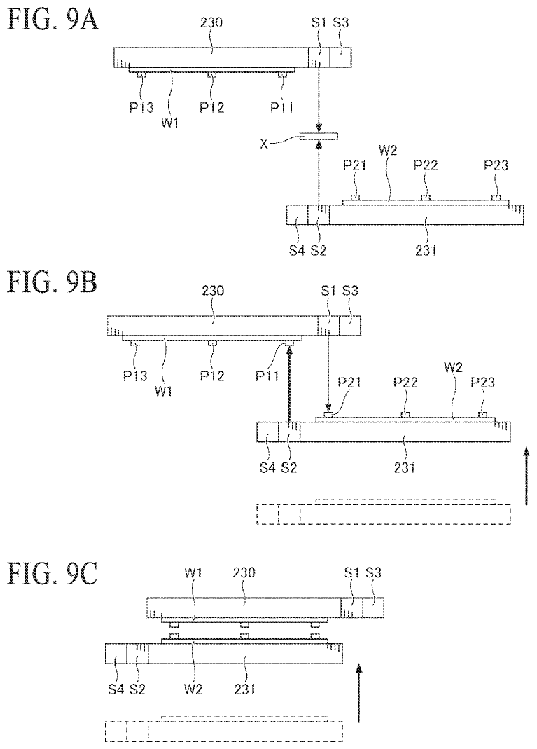

Then, the control device 90 controls the moving mechanism 290 to move the relative positions of the upper chuck 230 and the lower chuck 231 from the substrate delivery position to the bonding position shown in FIG. 7 (process S112). In this process S112, the control device 90 carries out alignment between the upper wafer W1 and the lower wafer W2 by using a first camera S1 and a second camera S2 as shown in FIG. 9A to FIG. 9C.

The first camera S1 is fixed to the upper chuck 230 to image the lower wafer W2 held by the lower chuck 231. Multiple reference points P21 to P23 are previously formed on the bonding surface W2j of the lower wafer W2. As the reference points P21 to P23, patterns of electronic circuits or the like may be used. The number of the reference points is not particularly limited.

Meanwhile, the second camera S2 is fixed to the lower chuck 231 to image the upper wafer W1 held by the upper chuck 230. Multiple reference points P11 to P13 are formed in advance on the bonding surface W1j of the upper wafer W1. As the reference points P11 to P13, patterns of electronic circuits or the like may be used. The number of these reference points is not particularly limited.

As depicted in FIG. 9A, the bonding module 41 adjusts the relative positions of first camera S1 and second camera S2 in a horizontal direction through the use of the moving mechanism 290. Specifically, the moving mechanism 290 moves the lower chuck 231 in the horizontal direction such that the second camera S2 is positioned substantially directly below the first camera S1. Then, the first camera S1 and the second camera S2 image a common target X and the moving mechanism 290 finely adjusts the position of the second camera S2 in the horizontal direction such that the positions of the first camera S1 and the second camera S2 in the horizontal direction are coincident.

Subsequently, as shown in FIG. 9B, the moving mechanism 290 moves the lower chuck 231 vertically upwards to adjust the positions of the upper chuck 230 and the lower chuck 231 in the horizontal direction. Specifically, while the moving mechanism 290 is moving the lower chuck 231 in the horizontal direction, the first camera 51 sequentially images the reference points P21 to P23 of the lower wafer W2, and the second camera S2 sequentially images the reference points P11 to P13 of the upper wafer W1. FIG. 9B shows a state in which the first camera 51 is imaging the reference point P21 of the lower wafer W2 and the second camera S2 is imaging the reference point P11 of the upper wafer W1.

The first camera 51 and the second camera S2 transmit the obtained image data to the control device 90. The control device 90 controls the moving mechanism 290 based on the image data obtained by the first camera 51 and the image data obtained by the second camera S2, and adjusts the position of the lower chuck 231 in the horizontal direction such that the reference points P11 to P13 of the upper wafer W1 and the reference points P21 to P23 of the lower wafer W2 coincide with each other when viewed from the vertical direction.

Thereafter, as illustrated in FIG. 9C, the moving mechanism 290 moves the lower chuck 231 vertically upwards. As a result, a distance G (see FIG. 7) between the bonding surface W2j of the lower wafer W2 and the bonding surface W1j of the upper wafer W1 becomes a predetermined distance of, e.g., 80 μm to 200 μm. The adjustment of the distance G is performed by using a first displacement meter S3 and a second displacement meter S4.

The first displacement meter S3 is fixed to the upper chuck 230, like the first camera S1, and measures the thickness of the lower wafer W2 held by the lower chuck 231. The first displacement meter S3 measures the thickness of the lower wafer W2 by, for example, radiating light to the lower wafer W2 and receiving reflected light reflected from both top and bottom surfaces of the lower wafer W2. This thickness measurement is performed when the moving mechanism 290 moves the lower chuck 231 in the horizontal direction, for example. The first displacement meter S3 carries out the measurement by, for example, a confocal method, a spectral interference method, or a triangulation method. A light source of the first displacement meter S3 is an LED or a laser.

Meanwhile, the second displacement meter S4 is fixed to the lower chuck 231, like the second camera S2, and measures the thickness of the upper wafer W1 held by the upper chuck 230. The second displacement meter S4 measures the thickness of the upper wafer W1 by, for example, radiating light to the upper wafer W1 and receiving reflected light reflected from both top and bottom surfaces of the upper wafer W1. This thickness measurement is performed when the moving mechanism 290 moves the lower chuck 231 in the horizontal direction, for example. The second displacement meter S4 carries out the measurement by, for example, a confocal method, a spectral interference method, or a triangulation method. A light source of the second displacement meter S4 is an LED or a laser.

The first displacement meter S3 and the second displacement meter S4 transmit the measured data to the control device 90. The control device 90 controls the moving mechanism 290 based on the data obtained by the first displacement meter S3 and the data obtained by the second displacement meter S4, and adjusts the position of the lower chuck 231 in the vertical direction such that the distance G becomes the set value.

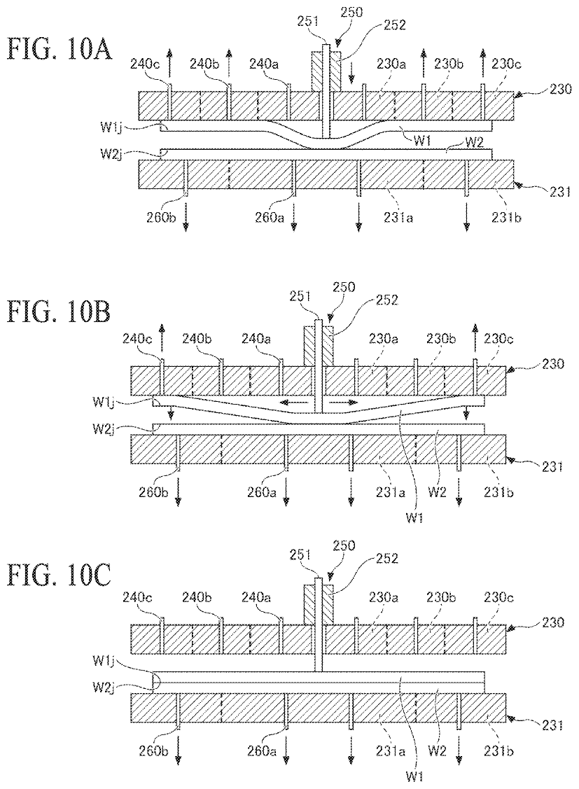

Next, the operation of the vacuum pump 241a is stopped. As a result, as shown in FIG. 10A, the vacuum attraction of the upper wafer W1 in the region 230a is canceled. Thereafter, the pushing pin 251 of the pushing member 250 is lowered to press the center of the upper wafer W1, allowing the upper wafer W1 to come into contact with the lower wafer W2 (process S113). As a result, the centers of the upper and lower wafers W1 and W2 are bonded to each other.

Since the bonding surface W1j of the upper wafer W1 and the bonding surface W2j of the lower wafer W2 are modified, a van der Waals force (intermolecular force) is first generated between the bonding surfaces W1j and W2j, so that the bonding surfaces W1j and W2j are bonded to each other. Further, since the bonding surface W1j of the upper wafer W1 and the bonding surface W2j of the lower wafer W2 have been hydrophilized, hydrophilic groups (e.g., OH groups) are hydrogen-bonded, allowing the bonding surfaces W1j and W2j to be firmly bonded to each other.

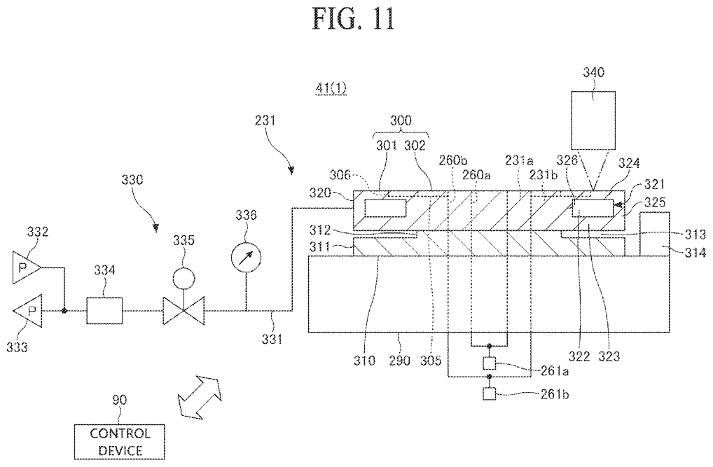

Subsequently, the control device 90 stops the operation of the vacuum pump 241b, and cancels the vacuum attraction of the upper wafer W1 in the region 230b, as shown in FIG. 11B. Afterwards, the control device 90 stops the operation of the vacuum pump 241c, and cancels the vacuum attraction of the upper wafer W1 in the region 230c, as shown in FIG. 11C.

In this way, the vacuum attraction of the upper wafer W1 is released step by step from the center toward a periphery of the upper wafer W1, so that the upper wafer W1 drops and comes into contact with the lower wafer W2 step by step. Then, the bonding of the upper wafer W1 and the lower wafer W2 proceeds sequentially from the centers toward the peripheries of the upper and lower wafers W1 and W2 (process S114). As a result, the entire bonding surface W1j of the upper wafer W1 and the entire bonding surface W2j of the lower wafer W2 come into contact with each other, so that the upper wafer W1 and the lower wafer W2 are bonded together, and the combined wafer T is obtained. Then, the bonding apparatus 1 raises the pushing pin 251 to its original position.

After the combined wafer T is formed, the control device 90 controls the moving mechanism 290 to move the relative positions of the upper chuck 230 and the lower chuck 231 from the bonding positions shown in FIG. 7 to the substrate delivery positions shown in FIG. 5 and FIG. 6 (process S115). By way of example, the moving mechanism 290 first lowers the lower chuck 231 to widen the distance between the lower chuck 231 and the upper chuck 230 in the vertical direction. Then, the moving mechanism 290 moves the lower chuck 231 sideways so that the lower chuck 231 and the upper chuck 230 are placed sideways apart.

Thereafter, the control device 90 controls the transfer device 61 to carry out the combined wafer T from the bonding module 41 (process S116). Specifically, the lower chuck 231 first releases the holding of the combined wafer T. Then, the plurality of holding pins 265 are raised to hand the combined wafer T over to the transfer device 61. Thereafter, the plurality of holding pins 265 are lowered to their original positions.

Next, the configuration of the lower chuck (holder) 231 according to the present exemplary embodiment will be described with reference to FIG. 11. The lower chuck 231 has a function of changing a height (shape) of an outer peripheral side of the attraction surface 300 and maintaining it in order to correct a distortion of an outer peripheral portion of the lower wafer W2. In FIG. 11 and the following drawings, the attraction surface 300 is illustrated as a flat shape. However, the attraction surface 300 may be provided with a plurality of ribs extending in the radial direction and a plurality of ribs arranged along the circumferential direction.

Here, in the combined wafer T in which the upper wafer W1 and the lower wafer W2 are bonded, when deviations between the reference points P11 to P13 of the upper wafer W1 and the reference points P21 to P23 of the lower wafer W2 are measured after the upper and lower wafers W1 and W2 are bonded, the deviations between the reference points tend to increase at an outer peripheral portion of the combined wafer T. This is because, in the upper wafer W1 and the lower wafer W2 before being bonded, distortion of the bonding surfaces W1j and W2j tends to be manifested at their outer peripheral sides rather than at center sides thereof. For this reason, the lower chuck 231 controls the height of the outer peripheral side of the attraction surface 300 to expand or contract the bonding surfaces W1j and W2j based on the difference in the relative distortion of the outer peripheral portions of the upper wafer W1 and the lower wafer W2, thus reducing the deviations between the reference points.

Specifically, the attraction surface 300 of the lower chuck 231 has an outer attraction portion 301 configured to attract the outer peripheral portion of the lower wafer W2 and an inner attraction portion 302 configured to attract a portion of the lower wafer W2 inside the outer peripheral portion. The inner attraction portion 302 is formed in a circular shape when viewed from the top, and the outer attraction portion 301 is formed in an annular shape to be adjacent to the inner attraction portion 302 at an outside thereof.

The inner attraction portion 302 has the aforementioned regions 231a and 231b (see FIG. 7). The outer attraction portion 301 overlaps a part of the region 231b, and is configured to apply an attracting pressure of the region 231b to the outer peripheral portion of the lower wafer W2. For example, in the lower chuck 231, the portion where the outer attraction portion 301 is formed includes a plurality of internal paths 305 extending outwards in the radial direction from the suction lines 260b (see FIG. 7), and attraction holes 306 respectively extending from the internal paths 305 to the attraction surface 300 (outer attraction portion 301). With this configuration, the lower chuck 231 attracts a region of the lower wafer W2 ranging from the center to the outer peripheral portion thereof by the inner attraction portion 302, while attracting the outer peripheral portion of the lower wafer W2 by the outer attraction portion 301.

The lower chuck 231 has, at an inside and an outside thereof, a function of transforming the outer attraction portion 301 relative to the inner attraction portion 302. Specifically, the lower chuck 231 has a base member 310 mounted to the moving mechanism 290 and a holding member 320 stacked on the base member 310 to hold the lower wafer W2 directly. Further, the lower chuck 231 also has, at an outer peripheral side of the holding member 320, a transforming unit 321 configured to transform the outer attraction portion 301.

The base member 310 has, in a side cross sectional view along a vertical direction (see FIG. 11), a protruding shape in which a base 311 fixed to the moving mechanism 290 (a moving stage of the moving mechanism 290) and a short protruding portion 312 protruding vertically upwards from a central portion of the base 311 are provided. By fixing a surface (rear surface) of the holding member 320 opposite to the inner attraction portion 302 to an upper end surface of the protruding portion 312, the base member 310 supports the entire holding member 320 in a horizontal direction.

Thus, in the lower chuck 231, a clearance 313 (that is, a gap between members) is formed between a top surface of the base 311 of the base member 310 and a rear surface (for example, a bottom surface) of the outer attraction portion 301 of the holding member 320 at an outside of the protruding portion 312 in the radial direction. Here, in the bonding module 41, a mirror 314 configured to reflect light of a displacement meter (not shown) that measures a position in the horizontal direction while being moved in three-dimensional directions by the moving mechanism 290 is disposed near the lower chuck 231. The mirror 314 and the base member 310 are spaced apart from each other on the moving stage of the moving mechanism 290. In a configuration where the base member 310 is transformed according to the transformation of the transforming unit 321 of the lower chuck 231, there is a likelihood that the transformation may affect the reflection of the mirror 314 adjacent to the base member 310.

For this reason, the lower chuck 231 does not support the rear surface of the outer attraction portion 301 with the base member 310, thus suppressing the base member 310 from being affected by the transformation of the outer attraction portion 301. That is, even when the bonding apparatus 1 has a configuration in which the outer attraction portion 301 is transformed, measurement precision near the lower chuck 231 can be improved by stabilizing the reflection of the mirror 314, and, therefore, positioning of the lower chuck 231, and so forth can be carried out stably.

Further, the holding member 320 according to the present exemplary embodiment has a transformation space 322 constituting the transforming unit 321 under the outer attraction portion 301 (that is, at an inside of the holding member 320 overlapping the outer attraction portion 301 in the vertical direction). When viewed on a cross section along the vertical direction, the transformation space 322 is a space surrounded by a lower wall 323, an upper wall 324, an outer peripheral wall 325, and an inner peripheral wall 326 of the holding member 320. The transformation space 322 is formed to have a rectangular shape with a long side in the horizontal direction in the state that it has a pressure equal to a pressure outside the holding member 320. The lower wall 323, the upper wall 324, the outer peripheral wall 325, and the inner peripheral wall 326 may be an integrally molded member, or some of the walls may be made of a different member from the others. For example, in the holding member 320, the lower wall 323 may be made of a (hard) material having a high elastic modulus, while the upper wall 324, the outer peripheral wall 325, and the inner peripheral wall 326 may be formed of a (softer) material having an elastic modulus lower than that of the lower wall 323.

The upper wall 324 forming the transformation space 322 is provided with the aforementioned internal paths 305 and attraction holes 306. The thickness of the upper wall 324 (between a front surface (for example, the top surface) of the outer attraction portion 301 and the transformation space 322) is set to be smaller than the thickness of the lower wall 323 (between the rear surface (for example, the bottom surface) of the outer attraction portion 301 and the transformation space 322). Accordingly, when an internal pressure of the transformation space 322 fluctuates, the upper wall 324 is greatly transformed, whereas most of the lower wall 323, the outer wall 325, and the inner wall 326 are not transformed. For this reason, in the lower chuck 231, the upper wall 324 is transformed according to fluctuations in the internal pressure of the transformation space 322, so that the outer attraction portion 301 can be transformed stably and reliably.

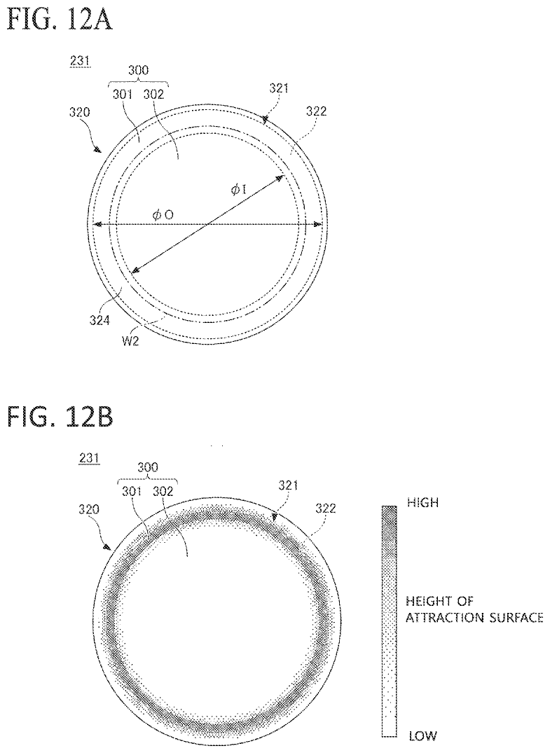

Further, as illustrated in FIG. 12A, the transformation space 322 is formed in an annular (ring) shape that goes around the inside of the holding member 320 forming the attraction surface 300. Accordingly, the internal pressure of the transformation space 322 is uniformly applied in the circumferential direction of the holding member 320. Thus, in the lower chuck 231, the outer attraction portion 301 can be uniformly transformed as a whole over the entire circumferential direction according to the fluctuations in the internal pressure of the transformation space 322.

By way of example, by increasing the internal pressure of the transformation space 322, the upper wall 324 expands (swells) over the entire circumferential direction of the holding member 320, as shown in FIG. 12B. Further, in FIG. 12B, a white color indicates the height (position) of the inner attraction portion 302 in the vertical direction, which is a reference on the attraction surface 300. Further, as the color becomes darker, it indicates that the height of the attraction surface 300 increases. In this way, by changing the height of the outer attraction portion 301 over the entire circumferential direction according to the transformation of the transforming unit 321, the lower chuck 231 is capable of transforming the outer peripheral portion of the lower wafer W2 uniformly.

Referring back to FIG. 11, in the bonding module 41, a fluid supply/exhaust unit 330 configured to supply or exhaust a fluid for transformation to/from the transformation space 322 is connected to a port in a side surface of the holding member 320. In the present exemplary embodiment, the fluid for transformation is air. However, the fluid for transformation is not merely limited to the air, and it may be an inert gas such as nitrogen (N₂) or a liquid such as water or oil.

The fluid supply/exhaust unit 330 has a supply/exhaust path 331 that is connected to the port of the holding member 320 and extended to the outside of the processing vessel 210. Further, the fluid supply/exhaust unit 330 is equipped with pumps (a booster pump 332 and a decompression pump 333), a regulator 334, a valve 335, and a pressure sensor 336 that are arranged in sequence from the upstream side of the supply/exhaust path 331 toward the downstream side thereof.

The booster pump 332 and the decompression pump 333 are branched off upstream of, for example, the regulator 334, and is configured to be operated independently under the control of the control device 90. The booster pump 332 supplies air to the holding member 320 to increase the internal pressure of the transformation space 322. The decompression pump 333 exhausts the air from the holding member 320 to reduce the internal pressure of the transformation space 322.

The regulator 334 is, for example, an electro-pneumatic regulator, and is configured to adjust the pressure of the air flowing through the supply/exhaust path 331 to a target pressure instructed by the control device 90. Further, the fluid supply/exhaust unit 330 is not limited to being equipped with only one regulator 334. For example, the regulator 334 may be applied to each of the booster pump 332 and the decompression pump 333.

The valve 335 serves to open and close a flow path within the supply/exhaust path 331 under the control of the control device 90. By way of non-limiting example, the valve 335 may be an air-operated valve (AOV) having a function of opening and closing the supply/exhaust path 331 and a function of opening it to the atmosphere to introduce or exhaust the air. With this configuration, by opening the valve 335 to the atmosphere when the transformation of the outer attraction portion 301 is completed, the transforming unit 321 can be restored immediately. Further, the number of the valve 335 is not limited to one, and each of the booster pump 332 and the decompression pump 333, for example, may be equipped with the valve 335.

The pressure sensor 336 detects the pressure of the air supplied to or exhausted from the holding member 320, and transmits the detection information to the control device 90. Based on this detection information from the pressure sensor 336, the control device 90 adjusts the amount of the air supplied to the transforming unit 321, and closes the valve 335 at an appropriate timing. In the state that the valve 335 is closed, the transformation space 322 is maintained at a predetermined internal pressure, so that the transformed state of the upper wall 324 can be maintained.

Furthermore, the bonding module 41 is equipped with a displacement sensor (measurement device) 340 vertically above the lower chuck 231 in order to detect a transformation amount of the outer attraction portion 301. For example, the displacement sensor 340 is disposed above the outer attraction portion 301 of the lower chuck 231 which is located at the substrate delivery position. The displacement sensor 340 performs the measurement by, for example, a confocal method, a spectral interferometry method, or a triangulation method. A light source of the displacement sensor 340 is an LED or a laser. The displacement sensor 340 is connected to the control device 90, and it measures the transformation amount of the outer attraction portion 301 in the state that the lower wafer W2 is not present on the attraction surface 300, and sends the measurement information to the control device 90.

The control device 90 may operate the transforming unit 321 based on the measurement result obtained by the displacement sensor 340. For example, the control device 90 stops the transformation of the transforming unit 321 when the outer attraction portion 301 is located at a target position. When the outer attraction portion 301 is not located at the target position, the transforming unit 321 is transformed according to the amount and the direction of the deviation from the target position. In FIG. 11, the single displacement sensor 340 is provided at a position facing the outer attraction portion 301, but a plurality of displacement sensors 340 may be provided along the circumferential direction of the outer attraction portion 301. The first displacement meter S3 applied to the upper chuck 230 may be used as the displacement sensor 340.

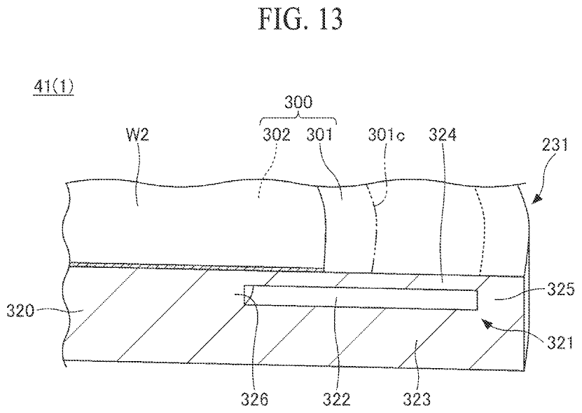

In addition, in the bonding module 41 according to the present exemplary embodiment, when the lower wafer W2 is placed on the attraction surface 300 of the lower chuck 231, the lower wafer W2 is transformed by using transformation at an inner side than a middle position 301c of the outer attraction portion 301 (transformation space 322) in a width direction thereof. For this reason, as shown in FIG. 13, when holding the lower wafer W2 on the attraction surface 300, the bonding module 41 determines the position of the lower wafer W2 such that the edge of the lower wafer W2 is located at the inner side than the middle position 301c of the outer attraction portion 301 in the width direction (hereinafter, referred to as widthwise middle position 301c of the outer attraction portion 301). Further, in FIG. 13, the widthwise middle position 301c of the outer attraction portion 301 is marked by a dashed double dotted line for convenience′ sake.

Since the edge of the lower wafer W2 is located at the inner side than the widthwise middle position 301c of the outer attraction portion 301, the range of the formation of the transformation space 322 is designed to have a size according to the size of the lower wafer W2. By way of example, when the diameter of the lower wafer W2 is 300 mm, a diameter ϕI of an inner peripheral wall 326 of the transformation space 322 may be set to be in the range of 270 mm to 280 mm, and a diameter ϕO of the outer peripheral wall 325 of the transformation space 322 may be set to be in the range of 340 mm to 350 mm (see FIG. 12A and FIG. 12B). In the present exemplary embodiment, the diameter (ϕI) of the inner peripheral wall 326 is set to be 276 mm, and the diameter (ϕO) of the outer peripheral wall 325 is set to be 346 mm. Accordingly, the width of the outer attraction portion 301 (transformation space 322) becomes 70 mm, and the widthwise middle position 301c of the outer attraction portion 301 becomes 35 mm. A distance from the center of the lower chuck 231 to the widthwise middle position 301c of the outer attraction portion 301 becomes 173 mm (138 mm+35 mm). A boundary between the outer attraction portion 301 and the inner attraction portion 302 may be defined by the inner peripheral wall 326. The outer attraction portion 301 may be regarded as the entire holding member 320 outside the inner peripheral wall 326 in the radial direction, or may be regarded as the formation range of the transformation space 322 (between the outer peripheral wall 325 and the inner peripheral wall 326). Alternatively, the boundary between the outer attraction portion 301 and the inner attraction portion 302 may be defined by a supporting portion (protruding portion 312) and a non-supporting portion (clearance 313) of the base member 310 (see FIG. 11). Furthermore, the ratio of the width of the outer attraction portion 301 to the radius of the inner attraction portion 302 is desirably set to be in the range of about ⅕ to about ⅗, for example.

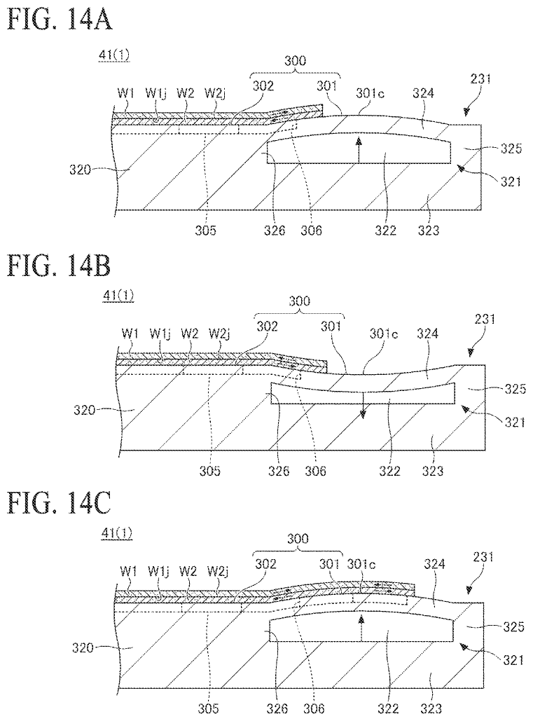

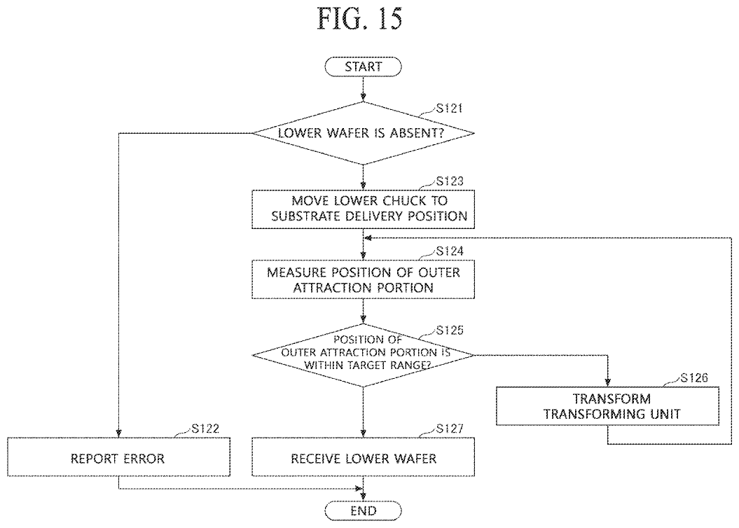

In the bonding module 41, by positioning the edge of the lower wafer W2 at the inner side than the widthwise middle position 301c of the outer attraction portion 301, the influence of the transformed shape of the transforming unit 321 at the inner side than the widthwise middle position 301c may be imposed on the upper wafer W1 and the lower wafer W2 when the transforming unit 321 is transformed into a mountain-like shape or a valley-like shape. For example, when the edge of the bonding surface W2j of the lower wafer W2 is relatively expanded as compared to that of the upper wafer W1, an operation of expanding the transforming unit 321 (upper wall 324) of the transformation space 322 is performed in order to contract the bonding surface W2j inwards (see FIG. 14A as well). On the contrary, when the edge of the bonding surface W2j of the lower wafer W2 is relatively contracted as compared to that of the upper wafer W1, an operation of contracting the transforming unit 321 (upper wall 324) of the transformation space 322 is performed in order to stretch the bonding surface W2j outwards (see FIG. 14B as well). In this way, the bonding apparatus 1 is capable of correcting the relative expansion or contraction of the upper wafer W1 and the lower wafer W2 with high precision by using the shape of the center side of the outer attraction portion 301 that has been transformed.

The bonding apparatus 1 according to the present exemplary embodiment is basically configured as described above, and an operation (a holding method of a substrate) thereof will be described below with reference to FIG. 15.

When holding the lower wafer W2 on the lower chuck 231 as a carrying-in process (process S111 in FIG. 8) of the lower wafer W2 in a manufacturing process of the combined wafer T, the control device 90 performs a process of appropriately adjusting the shape of the lower chuck 231. If, however, the lower chuck 231 is transformed in the state that the lower wafer W2 is attracted, the rear surface of the lower wafer W2 may be rubbed, and the transformation amount of the lower chuck 231 may be changed.

For this reason, the control device 90 adjusts the shape of the lower chuck 231 without the lower wafer W2 placed thereon. Specifically, the control device 90 first makes a determination upon whether or not the lower wafer W2 is present on the lower chuck 231 (process S121). For example, the control device 90 may detect the presence or absence of the lower wafer W2 by applying the attracting pressure to the attraction surface 300 and monitoring the attraction path and the pressure fluctuation of the vacuum pumps 261a and 261b at that time with a sensor or the like.

Then, when the lower wafer W2 is found to be present on the lower chuck 231 (process S121: NO), the processing proceeds to a process S122. In the process S122, the control device 90 reports an error indicating the presence of the lower wafer W2 through a non-illustrated monitor or the like of the control device 90. Further, when the lower chuck 231 has the combined wafer T and this combined wafer T is yet to be taken out, the control device 90 may perform an operation of taking out the combined wafer T by the transfer device 61. In addition, when the lower wafer W2 is present, the control device 90 may automatically perform an operation of taking out the lower wafer W2 by the transfer device 61 while notifying the error, and proceed to a process S123.

Meanwhile, if the lower wafer W2 is not present on the lower chuck 231 (process S121: YES), the processing proceeds to the process S123. In the process S123, the control device 90 operates the moving mechanism 290 to move the lower chuck 231 to the substrate delivery position.

Thereafter, the control device 90 measures the height (position in the vertical direction) of the outer attraction portion 301 of the lower chuck 231 by the displacement sensor 340 (process S124). Through this process, the control device 90 may recognize the current height of the outer attraction portion 301.

Subsequently, the control device 90 determines whether or not the height of the outer attraction portion 301 coincides with the target position (process S125). This target position is calculated in advance before the substrate processing. Specifically, a bending measuring device 5 (see FIG. 1) measures bending states (bending amounts and bending directions) of the upper wafer W1 and the lower wafer W2, and the control device 90 performs an appropriate calculation based on a difference in the bending state between the upper wafer W1 and the lower wafer W2.

Then, when the outer attraction portion 301 is not located at the target position (process S125: NO), the control device 90 proceeds to a process S126 to perform an operation of transforming the transforming unit 321. At this time, the control device 90 selectively performs a boosting process of increasing the internal pressure of the transformation space 322 or a decompressing process of reducing the internal pressure of the transformation space 322 according to the transformation direction and the transformation amount of the outer attraction portion 301 based on the relative difference in the bending state between the upper wafer W1 and the lower wafer W2.

For example, in case of performing the boosting process, by supplying air into the transformation space 322 through the fluid supply/exhaust unit 330, the upper wall 324 is raised (expanded) vertically upwards, as shown in FIG. 14A. At this time, the upper wall 324 is curved in an arc shape with the widthwise middle position 301c as an apex. Accordingly, after the lower chuck 231 is transformed, the lower wafer W2 whose edge is attracted to the inner side than the widthwise middle position 301c of the outer attraction portion 301 in the radial direction is held by the lower chuck 213 while having a shape inclined vertically upwards toward a radially outer side.

Therefore, when the outer peripheral portion of the bonding surface W2j of the lower wafer W2 is distorted so as to be stretched radially outwards as compared to the bonding surface W1j of the upper wafer W1, it is possible to hold the lower wafer W2 such that the lower wafer W2 contracts radially inwards when it is attracted. Alternatively, when the outer peripheral portion of the bonding surface W1j of the upper wafer W1 is distorted so as to be contracted radially inwards as compared to the bonding surface W2j of the lower wafer W2, it becomes possible to bond the upper wafer W1 such that it may be expanded radially outwards.

Meanwhile, in case of performing the decompressing process, the air is exhausted from the transformation space 322 by the fluid supply/exhaust unit 330, so that the upper wall 324 is recessed (contracted) downwards in the vertical direction, as shown in FIG. 14B. At this time, the upper wall 324 is curved in an arc shape with the widthwise middle position 301c as a bottom. For this reason, after the lower chuck 231 is transformed, the lower wafer W2 the edge of which is attracted to the inner side than the widthwise middle position 301c of the outer attraction portion 301 is held by the lower chuck 231, having a shape inclined vertically downwards toward a radially outer side.

Therefore, when the outer peripheral portion of the bonding surface W2j of the lower wafer W2 is distorted so as to be contracted radially inwards as compared to the bonding surface W1j of the upper wafer W1, it is possible to hold the lower wafer W2 such that it is expanded radially outwards when it is attracted. Alternatively, when the outer peripheral portion of the bonding surface W1j of the upper wafer W1 is distorted so as to be contracted radially inwards as compared to the bonding surface W2j of the lower wafer W2, it becomes possible to bond the upper wafer W1 such that it is contracted radially inwards.

Referring back to FIG. 15, the control device 90 monitors the position of the outer attraction portion 301 by repeating the processes S124 and S125 during the transformation operation of the transforming unit 321 in the process S126. Then, in the process S125, when it is determined that the position of the outer attraction portion 301 coincides with the target position (process S125: YES), the control device 90 stops the transformation operation of the transforming unit 321 and proceeds to a process S127. Further, when the outer attraction portion 301 is found to be located at the target position when measured by the displacement sensor 340 for the first time, the transformation operation of the transforming unit 321 is not performed, and the processing proceeds to the process S127.

In the process S127, the control device 90 performs an operation of receiving the lower wafer W2 from the transfer device 61 (see FIG. 1) onto the lower chuck 231 in which the position of the outer attraction portion 301 is adjusted to the target position. When receiving the lower wafer W2, the control device 90 allows the attraction surface 300 to exert an attracting pressure through the vacuum pumps 261a and 261b, so that the lower wafer W2 is attracted to the outer attraction portion 301 and the inner attraction portion 302. As described above, when the outer attraction portion 301 is expanded or contracted, the lower wafer W2 is held in the state that the outer peripheral portion thereof is transformed. Then, in the state that the lower wafer W2 is transformed, the bonding apparatus 1 moves the lower chuck 231 to the bonding position (process S112 in FIG. 8) to bond the lower wafer W2 to the upper wafer W1 (processes S113 and S114 of FIG. 8). Thus, the bonding apparatus 1 is capable of manufacturing the combined wafer T in which the deviations between the reference points at the outer peripheral portions are reduced.

As stated above, the bonding apparatus 1 according to the present exemplary embodiment transforms the outer attraction portion 301 relative to the inner attraction portion 302 by the transforming unit 321. Thus, the distortion of the outer peripheral portion of the lower wafer W2 (upper wafer W1) can be appropriately corrected. Accordingly, when a relatively large distortion occurs at the outer peripheral portion of the bonding surface W2j of the lower wafer W2 as compared to the outer peripheral portion of the bonding surface W1j of the upper wafer W1, the distortion of the lower wafer W2 can be sufficiently corrected so that it can be bonded to the upper wafer W1. As a result, the bonding apparatus 1 is capable of producing the combined wafer T in which the deviations between the reference points P11 to P13 of the upper wafer W1 and the reference points P21 to P23 of the lower wafer W2 are reduced.

In particular, in the bonding apparatus 1 according to the first exemplary embodiment, the outer attraction portion 301 is transformed (expanded and contracted) through the supply/exhaust of the air to/from the transformation space 322, so that the outer attraction portion 301 can be easily transformed. Since the transforming unit 321 can be transformed without complicating the structure of the holding member 320 by the transformation space 322, the lower chuck 231 can be reduced in thickness. In addition, in the bonding apparatus 1, since the front surface (for example, top surface) of the outer attraction portion 301 and the front surface (for example, top surface) of the inner attraction portion 302 are continuous on the same plane, the lower wafer W2 can be stably supported without being shaken at the boundary between the outer attraction portion 301 and the inner attraction portion 302 even in the configuration in which the outer attraction portion 301 is transformed. In addition, by transforming the outer attraction portion 301 while measuring the position of the outer attraction portion 301 by the displacement sensor 340, the control device 90 is capable of transforming the outer attraction portion 301 to the target position reliably.

In addition, the bonding apparatus 1 and the holding method of the substrate are not limited to the above-described examples, and various modification examples may be taken. For example, the substrate processing apparatus is not limited to the bonding apparatus 1, and the present disclosure may be applied to an apparatus having a chuck (holder) configured to hold a substrate and performing a substrate processing related to in-plane uniformity of the substrate. As an example, in a film forming apparatus (substrate processing apparatus), by performing a film forming process (substrate processing) in the state that a distortion of an outer peripheral portion of the substrate is improved through the transformation of the outer attraction portion 301, the thickness of a film to be formed can be adjusted with high precision.

Further, as shown in FIG. 14C, in the bonding apparatus 1, the edge of the lower wafer W2 may be positioned outside the widthwise middle position 301c of the outer attraction portion 301. When the expansion and the contraction differ depending on the positions on the lower wafer W2 in the radial direction due to the structural factors of the lower wafer W2, the correction through both the expansion and the contraction may be performed on the bonding surface W2j by using the transformation of the outer attraction portion 301, so that the correction of the outer peripheral portion thereof can be further optimized.

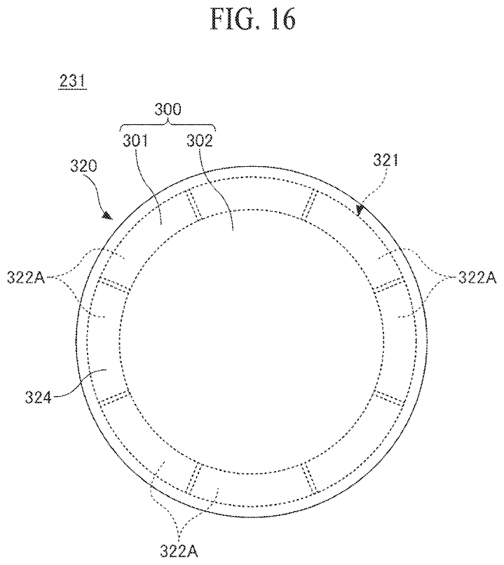

In addition, as shown in FIG. 16, the transforming unit 321 configured to transform the outer attraction portion 301 may have a plurality of transformation spaces 322A separated along the circumferential direction of the lower chuck 231, and the air may be supplied to and exhausted from each of the plurality of transformation spaces 322A individually. With this configuration, the lower chuck 231 is capable of individually adjusting the transformation amount of the outer attraction portion 301 in the circumferential direction according to the distortion of the lower wafer W2 (or the upper wafer W1). For example, when the bonding surface W2j in the X-axis direction is expanded while the bonding surface W2j in the Y-axis direction is contracted, the outer attraction portion 301 may pressurize the transformation space 322A in the X-axis direction and decompress the transformation space 322A in the Y-axis direction. That is, the bonding apparatus 1 is capable of appropriately performing correction according to a difference in the relative expansion/contraction (distortion) of the lower wafer W2 and the upper wafer W1. In addition, although eight transformation spaces 322A separated from each other are illustrated in FIG. 16, the number of divisions and the volume of each space can be designed as required.

### Second Exemplary Embodiment

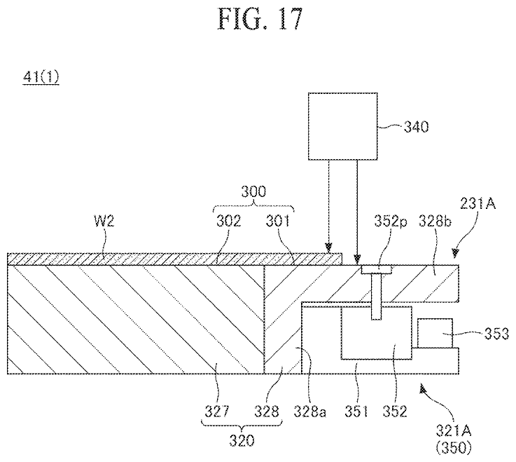

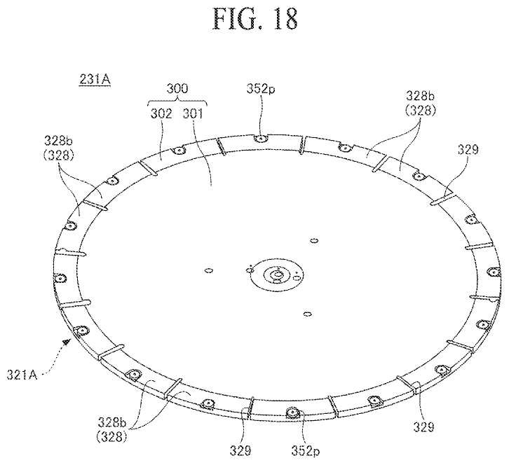

Now, a lower chuck 231A according to a second exemplary embodiment will be described with reference to FIG. 17 and FIG. 18. This lower chuck 231A is different from the lower chuck 231 of the first exemplary embodiment in that a mechanical unit 350 having an actuator (driving source) performs the transformation of the outer attraction portion 301 mechanically regardless of the supply/exhaust of the fluid for transformation.

Specifically, a holding member 320 of the lower chuck 231A has a disc-shaped inner support 327, and a plurality of arc-shaped outer supports 328 provided adjacent to the inner support 327 at an outside thereof. For example, the inner support 327 and the outer supports 328 are made of different members, and by fixing them with appropriate fixing members such as screws, the attraction surface 300 having a substantially flat shape is formed by top surfaces of the inner support 327 and the outer supports 328. Further, the holding member 320 may have a configuration in which the inner support 327 and the outer supports 328 are molded as one body.

The outer support 328 is made of a material having an elastic modulus lower than that of the inner support 327. In a side cross sectional view along a vertical direction, the outer support 328 has an L-shape with a vertical portion 328a fixed to the inner support 327, and a horizontal portion 328b projecting horizontally from an upper end of the vertical portion 328a. A top surface of the horizontal portion 328b forms the outer attraction portion 301 of the attraction surface 300, and a top surface of the inner support 327 forms the inner attraction portion 302 of the attraction surface 300. That is, the lower chuck 231A has a transforming unit 321A configured to transform the horizontal portion 328b of the outer support 328 in a height direction thereof.

The transforming unit 321A includes a bracket 351, a piezo actuator 352 configured to operate the outer support 328, and a control sensor 353 configured to detect the position of the outer support 328.

The bracket 351 is fixed to the vertical portion 328a of the outer support 328. The bracket 351 holds the piezo actuator 352 and the control sensor 353 in a space where the outer support 328 is notched.

The piezo actuator 352 advances a pin portion 352p based on a power feed to a non-illustrated piezoelectric element, and retracts the pin portion 352p when the power feed to the piezoelectric element is stopped. This piezo actuator 352 is capable of controlling the position of the pin portion 352p with high precision in a range of several nanometers (nm) to hundreds of micrometers (μm) depending on the power applied thereto.

The pin portion 352p is vertically projected from a body of the piezo actuator 352. An upper end of the pin portion 352p is fixed to the opposing horizontal portion 328b of the outer support 328 by an appropriate fixing member (screwing, welding, etc.). Therefore, the horizontal portion 328b is curved vertically upwards toward a radially outer side as the pin portion 352p rises, while it is curved vertically downwards toward the radially outer side as the pin portion 352p descends.

The control sensor 353 is a sensor that measures the position of the outermost side of the horizontal portion 328b in the vertical direction, and is connected to the control device 90 so as to communicate information therebetween. As an example of this type of control sensor 353, a capacitance sensor, an optical displacement sensor, a strain sensor, or the like may be used. When the piezo actuator 352 is driven, the control device 90 controls the power fed to the piezo actuator 352 based on the measurement information detected by the control sensor 353.

Further, the lower chuck 231A is provided with the displacement sensor 340 vertically above the horizontal portion 328b of the outer support 328, and the position of the horizontal portion 328b or the position of the lower wafer W2 may be measured by the displacement sensor 340. The control device 90 may adjust the power fed to the piezo actuator 352 based on the measurement information of the displacement sensor 340.

Furthermore, as illustrated in FIG. 18, the lower chuck 231A is equipped with the outer supports 328 separated along the circumferential direction of the outer attraction portion 301. Slits 329 each extending along the radial direction is formed between the outer supports 328 adjacent to each other. The slits 329 reach the inner support 327, so they completely separate the respective outer supports 328 from each other. The lower chuck 231A is equipped with the transforming unit 321A (the bracket 351, the piezo actuator 352, and the control sensor 353) for each of the plurality of outer supports 328, and is thus capable of transforming the respective horizontal portions 328b independently.

As described above, the bonding apparatus 1 is capable of appropriately transforming each outer attraction portion 301 by using the plurality of mechanical units 350 configured to transform the outer supports 328 that are arranged along the circumferential direction of the outer attraction portion 301. In particular, since the mechanical unit 350 employs the piezo actuator 352 as a driving source, each outer attraction portion 301 can be transformed with high precision under the control of the control device 90.

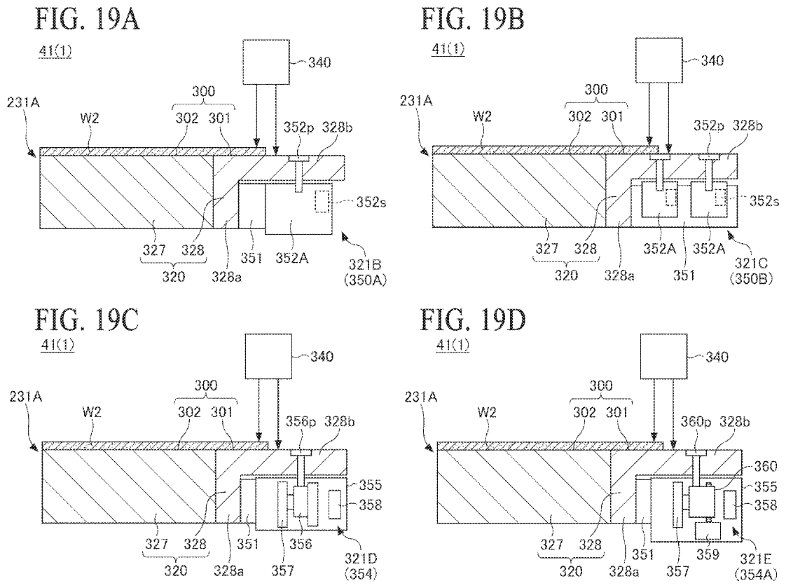

In addition, the lower chuck 231A may have a configuration in which the outer attraction portion 301 is formed to be continuous along the circumferential direction, and the outer attraction portion 301 in the entire circumferential direction is transformed by operating the plurality of transforming unit 321A at the same time. Further, the transforming unit 321A configured to transform the horizontal portion 328b of the outer support 328 is not limited to the mechanism shown in FIG. 17, and it may adopt various configurations. Hereinafter, with reference to FIG. 19A to FIG. 19D, configurations of the transforming unit 321A will be described.

A transforming unit 321B (mechanical unit 350A) shown in FIG. 19A employs a piezo actuator 352A having a strain sensor 352s embedded therein. The strain sensor 352s may play the same role as the above-described control sensor 353 by detecting a displacement of the pin portion 352p and transmitting the information to the control device 90. This makes it possible to omit the control sensor 353 from the transforming unit 321B. Thus, the bracket 351 of a simple shape for fixing the piezo actuator 352A can be applied to the transforming unit 321B, so that the overall configuration is further simplified.

A transforming unit 321C (mechanical unit 350B) shown in FIG. 19B is equipped with a plurality of piezo actuators 352A along the radial direction of the outer attraction portion 301. In this case, the bracket 351 is formed to have a plurality of recessed portions to accommodate the respective piezo actuators 352A therein. Each piezo actuator 352A has a strain sensor 352s embedded therein, and is thus capable of detecting a displacement of each pin portion 352p. The control device 90 controls the displacements of the piezo actuators 352A arranged in the radial direction individually, thus enhancing the transformation of the outer attraction portion 301 or allowing the outer attraction portion 301 to have various shapes by being curved into a mountain-like shape or a valley-like shape.

A transforming unit 321D depicted in FIG. 19C is equipped with a linear mechanism 354 instead of the mechanical unit 350 having the piezo actuator 352. Specifically, the transforming unit 321D holds a housing 355 of the linear mechanism 354 by the bracket 351, and has a linear motor 356, a linear guide 357, and a linear scale 358 in the housing 355.

The linear motor 356 is connected to the control device 90, and is displaced on the linear guide 357 based on a power fed from the control device 90. The linear guide 357 extends along the vertical direction. With this configuration, the transforming unit 321D raises and lowers (displaces) a pin portion 356p protruded from the linear motor 356 to transform the horizontal portion 328b of the outer support 328 to which the pin portion 356p is connected. The control device 90 is capable of appropriately adjusting a transformation direction and a transformation amount of the horizontal portion 328b by displacing the linear motor 356 while detecting the position of the linear motor 356 with the linear scale 358.

A transforming unit 321E shown in FIG. 19D is equipped with, as another linear mechanism 354A, the linear guide 357, the linear scale 358, a servo motor 359, and a ball screw mechanism 360 in the housing 355. That is, this linear mechanism 354A advances and retracts a pin portion 360p connected to a movable body of the ball screw mechanism 360 by adjusting a power pulse supplied to the servo motor 359 and converting a rotation of the servo motor 359 into a linear motion in the ball screw mechanism 360. In this case as well, the control device 90 is capable of appropriately adjusting the transformation direction and the transformation amount of the horizontal portion 328b.

It should be noted that the substrate processing apparatus (bonding apparatus 1) and the holding method of the substrate according to the above-described exemplary embodiments are illustrative in all aspects and are not anyway limiting. The above-described exemplary embodiments can be modified and improved in various ways without departing from the scope and the spirit of appended claims. Unless contradictory, other configurations may be adopted, and the disclosures in the various exemplary embodiments can be combined appropriately.

According to the exemplary embodiment, it is possible to appropriately correct the distortion of the outer peripheral portion of the substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus, comprising:
a holder configured to hold a substrate by attracting the substrate on an attraction surface,
wherein the attraction surface comprises an outer attraction portion configured to attract an outer peripheral portion of the substrate and an inner attraction portion configured to attract a portion of the substrate at an inner side than the outer peripheral portion, and
the holder comprises a transforming unit configured to transform the outer attraction portion relative to the inner attraction portion.

2. The substrate processing apparatus of claim 1,
wherein the transforming unit has a transformation space at an inside of the holder, the transformation space being located at a position corresponding to the outer attraction portion, and
the transforming unit is configured to supply a fluid into the transformation space to expand the outer attraction portion with respect to the inner attraction portion, and exhaust the fluid from the inside of the holder to contract the outer attraction portion with respect to the inner attraction portion.

3. The substrate processing apparatus of claim 2,
wherein the holder comprises a holding member having the attraction surface, and a base member supporting a rear surface of the holding member, and
the base member supports a rear surface of the inner attraction portion, while not supporting a rear surface of the outer attraction portion.

4. The substrate processing apparatus of claim 2,
wherein a thickness between a front surface of the outer attraction portion and the transformation space is smaller than a thickness between a rear surface of the outer attraction portion and the transformation space.

5. The substrate processing apparatus of claim 2,
wherein the transformation space is continuous in an annular shape along a circumferential direction of the holder.

6. The substrate processing apparatus of claim 1,
wherein the transforming unit comprises an outer support to be in contact with the substrate in the outer attraction portion, and a mechanical unit connected to the outer support and configured to transform the outer support.

7. The substrate processing apparatus of claim 6,
wherein the mechanical unit comprises a piezo actuator as a driving source configured to move the outer support up and down.

8. The substrate processing apparatus of claim 1,
wherein a front surface of the outer attraction portion and a front surface of the inner attraction portion are continuous with each other on a same plane.

9. The substrate processing apparatus of claim 1,
wherein the outer attraction portion is divided into multiple sections along a circumferential direction of the holder.

10. The substrate processing apparatus of claim 1,
wherein in a state that the substrate is attracted to the attraction surface such that a center of the attraction surface coincides with a center of the substrate, a middle position of the transforming unit in a width direction is located radially outside an edge of the substrate.

11. The substrate processing apparatus of claim 1, further comprising:
a measurement device configured to measure a position of the outer attraction portion; and
a controller configured to transform the transforming unit based on measurement information obtained by the measurement device,
wherein the controller stops a transformation of the transforming unit when it is found out that the measured position of the outer attraction portion coincides with a target position.

12. The substrate processing apparatus of claim 11,
wherein the controller transforms the transforming unit when the measured position of the outer attraction portion does not coincide with the target position.

13. The substrate processing apparatus of claim 1,
wherein the substrate processing apparatus is a bonding apparatus configured to bond the substrate attracted by the holder to another substrate disposed at an opposing position to the substrate.

14. A holding method of a substrate of holding the substrate by a holder having an attraction surface including an outer attraction portion configured to attract an outer peripheral portion of the substrate and an inner attraction portion configured to attract a portion of the substrate at an inner side than the outer peripheral portion, the holding method of the substrate comprising:
transforming the outer attraction portion relative to the inner attraction portion by a transforming unit provided in the holder; and
attracting the substrate by the outer attraction portion and the inner attraction portion after the outer attraction portion is transformed.
